(19) United States
(12) Patent Application Publication
(10) Pub. No.: US 2015/0129829 A1
(43) Pub. Date: May 14, 2015

(54) ONE TIME PROGRAMMABLE AND MULTI-LEVEL, TWO-TERMINAL MEMORY CELL

(71) Applicant: Crossbar, Inc., Santa Clara, CA (US)

(72) Inventor: Tanmay KUMAR, Santa Clara, CA (US)

(73) Assignee: Crossbar, Inc., Santa Clara, CA (US)

(21) Appl. No.: 14/079,606

(22) Filed: Nov. 13, 2013

(51) Int. Cl. H01L 27/24; H01L 45/00

(52) U.S. Cl. CPC H01L 27/2409; H01L 27/2463; H01L 45/085; H01L 45/1608; H01L 45/1641
USPC 257/5; 257/2; 438/382

(57) ABSTRACT

Providing for one time programmable, multi-level cell two-terminal memory is described herein. In some embodiments, the one time programmable, multi-level cell memory can have a 1 diode 1 resistor configuration, per memory cell. A memory cell according to one or more disclosed embodiments can be programmed to one of a set of multiple logical bits, and can be configured to mitigate or avoid erasure. Accordingly, the memory cell can be employed as a single program, non-erasable memory. Expressed differently, the memory cell can be referred to as a write once read many (WORM) category of memory.

### TECHNICAL FIELD

This application relates generally to two-terminal memory cell technology, e.g., a one time programmable multi-level memory cell.

### BACKGROUND

The inventors of the present disclosure have been focusing research in the area of resistive memory within the field of integrated circuit technology. While much of resistive memory technology is in the development stage, various technological concepts for resistive memory have been demonstrated by the inventors, and are in one or more stages of verification to prove or disprove associated theory(ies). The inventors believe that resistive memory technology promises to hold substantial advantages over semiconductor transistor-based technologies in the electronics industry.

The semiconductor transistor has been the basis of electronic memory and processing devices for the past several decades. Over time, advancement in technology has roughly followed Moore's Law, which predicts an increase in a number of semiconductor devices, such as transistors, that can be fabricated on a given geometric area of a semiconductor chip. One implication of increasing number of semiconductor devices is increasing memory capacity and processing power for the semiconductor chip and associated electronic devices. Moore's Law has been fairly accurate at predicting the advancement of semiconductor technology up to the present.

The inventors of the disclosed subject matter have worked with two-terminal memory devices, such as resistive memory, as a replacement for three-terminal semiconductor transistors. Based on their experience in the field, mathematical predictions and test results, the inventors believe that two-terminal memory devices can overcome drawbacks of three-terminal semiconductor transistors in various categories related to performance and reliability. Examples include write, erase and access times, data reliability, device density, and others. Accordingly, the inventors are in the process of discovering new ways to create or fabricate two-terminal memory technologies and how they can replace conventional micro electronic systems and devices.

### SUMMARY

The following presents a simplified summary of the specification in order to provide a basic understanding of some aspects of the specification. This summary is not an extensive overview of the specification. It is intended to neither identify key or critical elements of the specification nor delineate the scope of any particular embodiments of the specification, or any scope of the claims. Its purpose is to present some concepts of the specification in a simplified form as a prelude to the more detailed description that is presented in this disclosure.

Various embodiments of the subject disclosure provide for one time programmable, multi-level cell memory. In some embodiments, the one time programmable, multi-level cell memory can have a 1 diode 1 resistor configuration, per memory cell. A memory cell according to one or more disclosed embodiments can be programmed to one of a set of multiple logical bits, and can be configured to mitigate or avoid erasure. Accordingly, the memory cell can be employed as a single program, non-erasable ROM. Alternatively, the memory cell can be referred to as a write once read many (WORM) category of memory.

According to further embodiments, a disclosed memory cell is provided comprising a bipolar resistive switching component in series with a diode component. Further, the bipolar resistive switching component can be configured to form a conductive filament having one of a plurality of filament states, in response to a program bias. The program bias can be in a same direction as a forward bias of the diode component. Further, a reverse breakdown voltage of the diode component can be greater in magnitude than an erase voltage of the resistive switching component, and reverse current of the diode component can be smaller than an erase current of the resistive switching component. Accordingly, the diode component can effectively mitigate or avoid application of a suitable erase signal to the bipolar resistive switching component, thereby mitigating or avoiding erasure of the disclosed memory cell.

According to further embodiments, disclosed memory cells can be configured to have a set of conductive filament states that correspond respectively to a set of multiple logical bits, in one or more embodiments. By having multiple logical bits, the disclosed memory cells of this embodiment(s) can be multi-level cells, programmable to a selected one of the multiple logical bits. A program signal having one of a set of signal characteristics can form a conductive filament in a target memory cell having a corresponding one of the set of conductive filament states. By selecting the program signal to have a target one of the set of signal characteristics, the disclosed memory cells can be programmed to a selected one of the multiple logical bits. In various additional embodiments, the set of signal characteristics can include one or more program signal voltage values, one or more program signal current values, or one or more program signal pulse width values, or the like, or a suitable combination thereof.

In an additional embodiment(s), the subject disclosure provides a memory cell. The memory cell can comprise an ion donor layer configured to facilitate provision of free ions in response to a program signal applied to the memory cell. Moreover, the memory cell can comprise a resistive ion migration layer configured to receive ions from the ion donor layer to facilitate formation of a conductive filament within the resistive ion migration layer in response to the program signal, the conductive filament corresponding to one of a set of plural filament states that characterize the memory cell. In addition to the foregoing, the memory cell can comprise a diode component configured to facilitate current flow in a forward direction for the memory cell corresponding with ion migration from the ion donor layer to the resistive ion migration layer, and to resist current flow in a reverse direction.

In other embodiments, the subject disclosure provides a method of fabricating a memory cell. The method can comprise forming an ion donor layer as a first electrode of the memory cell and forming a resistive ion migration layer adjacent to the ion donor layer configured to receive free ions from the ion donor layer in response to a program bias applied to the memory cell. In various aspects of these embodiments, the free ions can form a conductive filament having one of multiple filament states in response to the program bias having a corresponding one of a set of signal characteristics. Further to the above, the method can comprise forming a diode component in electrical series with the ion donor layer and the resistive ion migration layer, wherein forming the diode component further comprises configuring the diode component for having a forward bias in a common direction as the program bias, and configuring the diode component to have a reverse bias current smaller than an erase bias current associated with deformation of the conductive filament.

In another embodiment(s), the subject disclosure provides an electronic device comprising an electronic memory unit, the electronic memory unit comprising one or more arrays of solid state multi-level memory cells configured to be one-time programmable to one of respective multiple bits of information. For example, one of the solid state multi-level memory cells can comprise a first electrode layer comprising free ions and a second layer adjacent to the first electrode layer, the second layer is at least in part permeable to the free ions and facilitates formation of a conductive filament having one of a set of plural filament states that facilitates programming the one of the solid state multi-level memory cells to one of a set of multiple logical bits. Moreover, the one of the solid state multi-level memory cells can comprise one or more layers forming a diode component configured to mitigate deformation of the conductive filament and erasing of the one of the set of multiple logical bits.

According to another embodiment, the subject disclosure provides a method of fabricating a memory. The method can comprise forming a channel region for an array of transistors in a semiconductor substrate, the channel region arranging the array of transistors electrically in series from source to drain and forming a set wordlines for the memory that serve as respective control gates for respective ones of the array of transistors. Furthermore, the method can comprise forming a set of two terminal switching devices arranged electrically in series from respective first terminals to respective second terminals of the set of two terminal switching devices and connecting one of the set of two terminal switching devices in parallel with one of the array of transistors.

### BRIEF DESCRIPTION OF THE DRAWINGS

Various aspects or features of this disclosure are described with reference to the drawings, wherein like reference numerals are used to refer to like elements throughout. In this specification, numerous specific details are set forth in order to provide a thorough understanding of this disclosure. It should be understood, however, that certain aspects of the subject disclosure may be practiced without these specific details, or with other methods, components, materials, etc. In other instances, well-known structures and devices are shown in block diagram form to facilitate describing the subject disclosure;

FIGS. 1A and 1B depict block diagrams of example one-time programmable, multi-level memory cells according to embodiments of the disclosure.

FIG. 2 depicts a sample diagram of a memory cell and corresponding circuit diagram, according to further embodiments.

FIG. 3 illustrates a block diagram of an example one-time programmable, multi-level memory cell according to another embodiment(s).

FIGS. 4A, 4B, 4C and 4D illustrate block diagrams of example conductive filaments for disclosed memory cells, in various disclosed embodiments.

FIG. 5 illustrates a block diagram of an example set of conductive filament states for a bipolar resistive switching component of a disclosed memory cell.

FIG. 6 depicts a circuit diagram of an example memory cell and related operation thereof according to further embodiments.

FIG. 7 illustrates a flowchart of a sample method for fabricating a memory cell, according to an embodiment(s).

FIG. 8 depicts a block diagram of a sample operating environment for facilitating implementation of one or more disclosed embodiments.

FIG. 9 illustrates a block diagram of an example computing environment that can be implemented in conjunction with various embodiments.

### DETAILED DESCRIPTION

This disclosure relates to two-terminal memory cells employed for digital information storage. In some embodiments, the two-terminal memory cells can include a resistive technology, such as a resistive-switching two-terminal memory cells. Resistive-switching two-terminal memory cells (also referred to as resistive-switching memory cells or resistive-switching memory), as utilized herein, comprise circuit components having two conductive contacts (also referred to herein as electrodes or terminals) with an active region between the two conductive contacts. The active region of the two-terminal memory device, in the context of resistive-switching memory, exhibits a plurality of stable or semi-stable resistive states, each resistive state having a distinct electrical resistance. Moreover, respective ones of the plurality of states can be formed or activated in response to a suitable electrical signal applied at the two conductive contacts. The suitable electrical signal can be a voltage value, a current value, a pulse width, a voltage or current polarity, or the like, or a suitable combination thereof. An example of a resistive switching two-terminal memory device, though not exhaustive, can include a resistive random access memory (RRAM).

Embodiments of the subject disclosure can provide a filamentary-based memory cell. One example of a filamentary-based memory cell can comprise: a p-type or n-type silicon (Si) bearing layer (e.g., p-type or n-type polysilicon, p-type or n-type SiGe, etc.), a resistive switching layer (RSL) and an active metal layer for providing filament forming ions to the RSL. The p-type or n-type Si bearing layer can include a p-type or n-type polysilicon, p-type or n-type SiGe, or the like. The RSL (which can also be referred to in the art as a resistive switching media (RSM)) can comprise, e.g., an undoped amorphous Si layer, a semiconductor layer having intrinsic characteristics, a Si sub-oxide, and so forth. Examples of the active metal layer can include, among others: silver (Ag), gold (Au), titanium (Ti), nickel (Ni), copper (Cu), aluminum (Al), chromium (Cr), tantalum (Ta), iron (Fe), manganese (Mn), tungsten (W), vanadium (V), cobalt (Co), platinum (Pt), palladium (Pd)), a metallic oxide (e.g. n+ doped zinc oxide). Other suitable conductive materials, as well as compounds or combinations of the foregoing can be employed for the active metal layer in some aspects of the subject disclosure. Some details pertaining to embodiments of the subject disclosure similar to the foregoing example can be found in the following U.S. patent applications that are licensed to the assignee of the present application for patent: application Ser. No. 11/875,541 filed Oct. 19, 2007 and application Ser. No. 12/575,921 filed Oct. 8, 2009, each of which are incorporated by reference herein in their respective entireties and for all purposes.

It should be appreciated that various embodiments herein may utilize a variety of memory cell technologies, having different physical properties. For instance, different resistive-switching memory cell technologies can have different discrete programmable resistances, different associated program/erase voltages, as well as other differentiating characteristics. For instance, various embodiments of the subject disclosure can employ a bipolar switching device that exhibits a first switching response (e.g., programming to one of a set of program states) to an electrical signal of a first polarity and a second switching response (e.g., erasing to an erase state) to the electrical signal having a second polarity. The bipolar switching device is contrasted, for instance, with a unipolar device that exhibits both the first switching response (e.g., programming) and the second switching response (e.g., erasing) in response to electrical signals having the same polarity and different magnitudes.

Where no specific memory cell technology or program/erase voltage is specified for the various aspects and embodiments herein, it is intended that such aspects and embodiments incorporate any suitable memory cell technology and be operated by program/erase voltages appropriate to that technology, as would be known by one of ordinary skill in the art or made known by way of the context provided herein. It should be appreciated further that where substituting a different memory cell technology would require circuit modifications that would be known to one of ordinary skill in the art, or changes to operating signal levels that would be known to one of such skill, embodiments comprising the substituted memory cell technology(ies) or signal level changes are considered within the scope of the subject disclosure.

The inventors of the present application are of the opinion that two-terminal memory devices, such as resistive-switching memory devices, have various advantages in the field of electronic memory. For example, resistive-switching technology can generally be small, consuming silicon area on the order of 4 F² per adjacent resistive-switching device for a single bit device (e.g., a memory cell comprising two resistive-switching devices would therefore be approximately 8 F² if constructed in adjacent silicon space). Non-adjacent resistive-switching devices, e.g., stacked above or below each other, can consume as little as 4 F² for a set of multiple non-adjacent devices. Moreover, multi-bit devices having two, three or more bits per memory cell can result in even greater densities in terms of bits per silicon area consumed. These advantages can lead to great semiconductor component density and memory density, and low manufacturing costs for a given number of digital storage bits. The inventors also believe that resistive-switching memory can exhibit fast programming speed and low programming current, and smaller cell sizes enabling greater component densities. Other benefits include non-volatility, having the capacity to store data without continuous application of power, and capacity to be built between metal interconnect layers, enabling resistive-switching based devices to be usable for two-dimension as well as three-dimension semiconductor architectures.

To program a filamentary-based resistive-switching memory cell, a suitable program voltage can be applied across the memory cell causing a conductive filament to form through a relatively high electrical resistance portion of the memory cell. This causes the memory cell to change from a relatively high resistive state, to a relatively low resistive state. In some resistive-switching devices, an erase process can be implemented to deform the conductive filament, at least in part, causing the memory cell to return to the high resistive state from the low resistive state. This change of state, in the context of memory, can be associated with respective states of a binary bit. Accordingly, multiple such memory cells can be programmed or erased to represent respective zeroes or ones of binary information, and by retaining those states over time in effect storing the binary information.

Further to the above, a multi-level resistive-switching memory cell can store one of multiple bits of digital information. The inventors of the subject application believe that multiple bit storage can be accomplished, in the context of resistive-switching media for instance, in response to multiple filament states that exhibit distinct electrical characteristics. For instance, a first filament state can exhibit a first electrical characteristic (e.g., a first current value, a first resistance value, a first voltage value, etc.), a second filament state can exhibit a second electrical characteristic measurably distinct from the first electrical characteristic, and so on. According to various digital information models, the number of filament states can be related to the number of digital bits that can be stored by the resistive switching device. In one example digital information model, the number of digital bits Y can be related to the number of filament states X by the following relationship:

X=2^{Y}.

According to this relationship, a memory cell capable of storing two digital bits can be achieved with four distinct filament states, a memory cell capable of storing three digital bits can be achieved with eight distinct filament states, and so on.

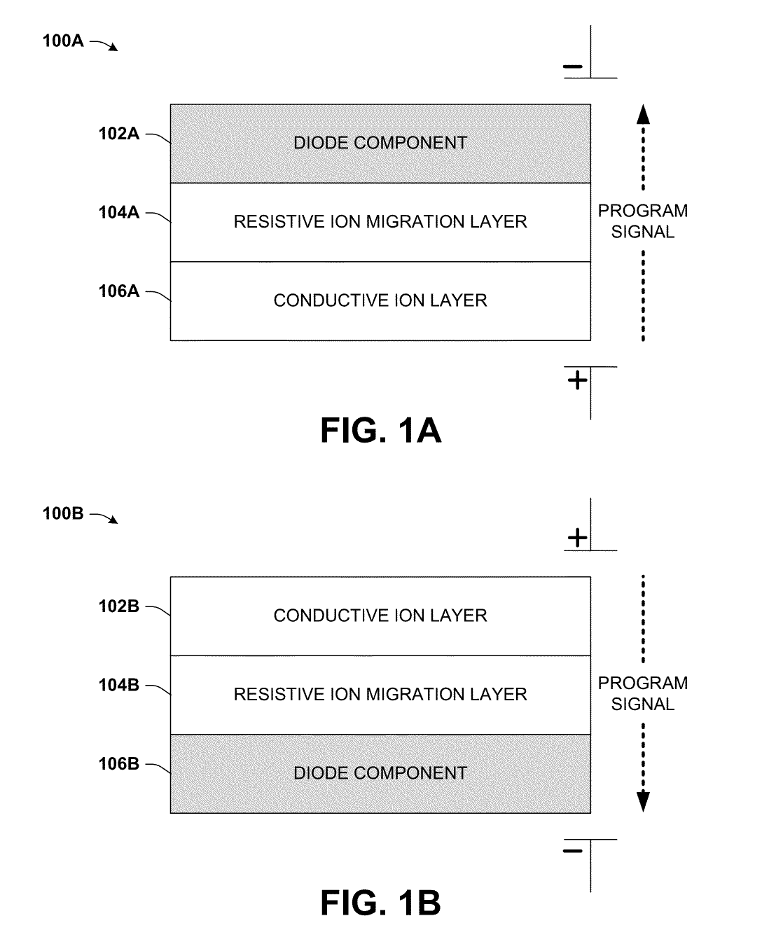

Referring now to the drawings, FIGS. 1A and 1B illustrate respective block diagrams of example memory cells 100A, 100B according to various embodiments of the subject disclosure. Referring first to FIG. 1A, a memory cell 100A is depicted having multi-level cell (MLC) one-time programmable (OTP) characteristics. For instance, memory cell 100A can store one of multiple bits of digital information (a multi-level cell), and can be configured to mitigate or avoid erasure of information stored by memory cell 100A (one-time programmable). Multi-level data storage can correspond to memory cell 100A offering greater memory density (in terms of bits per silicon space) as compared to single bit memory devices. In addition, the OTP characteristic can make this high memory density device suitable for write once, read many (WORM) memory devices. Such devices can be useful for ROM applications, where an electronic device provider desires to write configuration instructions, boot-time instructions, and so forth at time of manufacture of the electronic device, which can be read by the electronic device or applications thereof during normal operation (e.g., operation that does not induce catastrophic failure of memory cell 100A), but not erased during normal operation. In various embodiments, memory cell 100A can comprise a two-terminal MLC OTP memory cell, having high memory density, very fast read times, high data retention, high data longevity, and other benefits believed by the inventors to be achievable with two-terminal memory cells.

As depicted, memory cell 100A can comprise a diode component 102A adjacent to a resistive ion migration layer 104A and a conductive ion layer 106A adjacent to resistive ion migration layer 104A. Resistive ion migration layer 104A can be formed of a material having high electrical resistance (e.g., compared with conductive ion layer 106A). In addition, resistive ion migration layer 104A can be permeable or partly permeable to ions of conductive ion layer 106A. Suitable materials for resistive ion migration layer 104A can include a silicon material permeable to the ions, such as an amorphous silicon, a suitable silicon compound, a silicon germanium material, an oxide, a sub-oxide (e.g., SiO_{Z}, where Z is less than 2), a chalcogenide, a non-stoichiometric oxide of silicon (with or without germanium), a doped metallic oxide (e.g. n− doped Zinc Oxide) or the like, or a suitable combination thereof.

In one or more disclosed embodiments, the combination of resistive ion migration layer 104A and conductive ion layer 106A can form a bipolar resistive-switching device. A bipolar resistive-switching device can have a conductive filament formed in response to a suitable electric signal of a first polarity, and the conductive filament deformed or at least partially deformed in response to a suitable electric signal of a second polarity. For instance, a suitable electric signal of the first polarity applied to memory cell 100A can cause ions to form and flow from conductive ion layer 106A to resistive ion migration layer 104A and form a conductive filament within resistive ion migration layer 104A. A suitable electric signal of the second polarity applied to memory cell 100A after formation of such a conductive filament, can cause ions of the conductive filament to move back toward conductive ion layer 106A, and at least in part deforming the conductive filament.

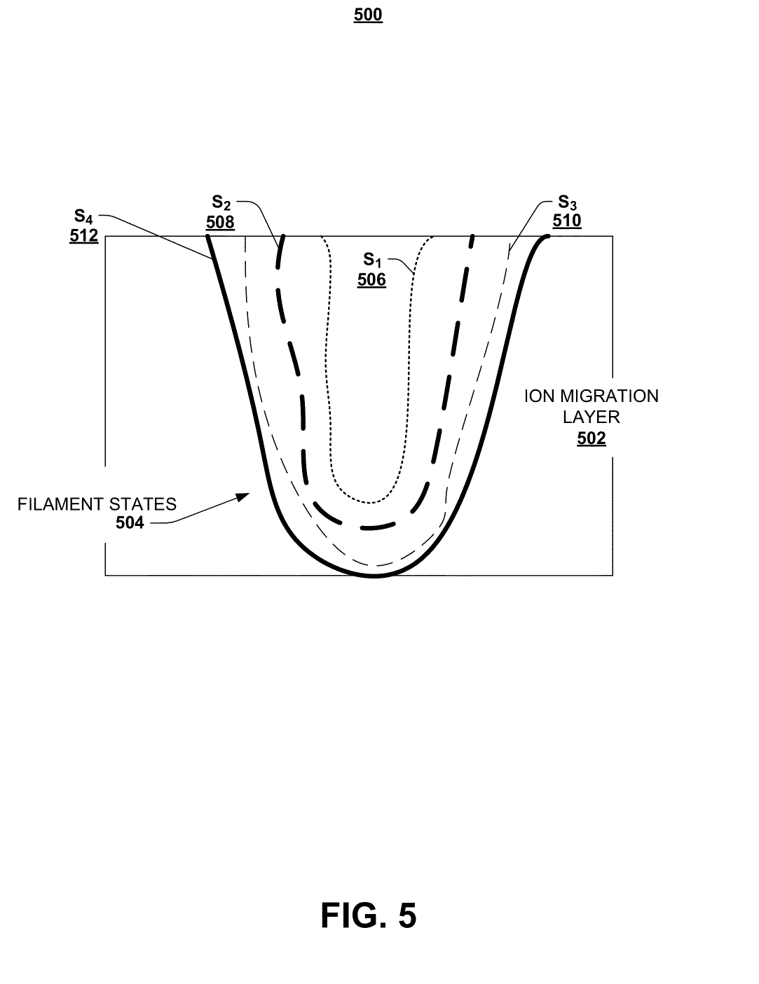

Conductive ion layer 106A can be formed of Ag, Au, Ti, Ni, Cu, Al, Cr, Ta, Fe, Mn, W, V, Co, Pt, or Pd, or the like, or a suitable compound of the foregoing, providing free ions that can migrate into resistive ion migration layer 104A in response to a suitable electric signal (e.g., a program signal having appropriate polarity). In some embodiments, free ions are not present in Conductive ion layer 106A absent application of an electric field across layer 106A. In some embodiments, upon application of an electric field across layer 106A, ions may be formed at a boundary between layer 106A, and provided into resistive ion migration layer 104A. Formation of a conductive filament within resistive ion migration layer 104A can result in modified electrical characteristics of resistive ion migration layer 104A due to formed ions, discussed above. In at least some embodiments, one of a set of electrical characteristics can result based on characteristics of the conductive filament. For instance, formation of a conductive filament having a particular size, shape, diameter, or traversing a particular width of resistive ion migration layer 104A can correspond with a particular set of electrical characteristics (e.g., current, resistance, voltage, or the like) that can be measured at memory cell 100A. In various embodiments, different sizes, shapes, diameters, widths, etc., of the conductive filament can form or be associated with one of a set of filament states. Moreover, the conductive filament can be selected to have one of the set of filament states in response to a program signal having a corresponding one of a set of signal characteristics, as described in more detail at FIG. 5, infra.

Diode component 102A can be configured to resist an electrical signal having a second polarity (e.g., an erase signal), opposite to a first polarity of the program signal. As depicted by FIG. 1A, a program signal oriented positive to negative from conductive ion layer 106A to diode component 102A can be a forward bias signal (e.g., a program signal of the first polarity, in a direction of the dotted arrow of the program signal) relative to diode component 102A. Diode component 102A can be configured to have a low forward bias voltage which, when exceeded, causes diode component 102A to be in a forward conductive state having a low resistance. In at least some embodiments, the forward conductive state of diode component 102A can be less resistive than any of the filament states of resistive ion migration layer 104A. Thus, for the forward bias voltage, resistive ion migration layer 104A is the primary limit on forward bias current of memory cell 100A. An erase signal having a reverse bias (electrical signal having the second polarity) can observe a high resistance at diode component 102A. In various embodiments, a reverse bias current of diode component 102A can be of lower magnitude than is suitable to deform a conductive filament formed at resistive ion migration layer 104A. Accordingly, once memory cell 100A is programmed with a conductive filament, diode component 102A can mitigate or avoid erasing of the programming. In this manner, memory cell 100A can operate as a one time programmable OTP memory cell, with an “off” state being a higher resistance characteristic, and an “on” or program state being a lower resistance characteristic.

In addition to the foregoing, memory cell 100A can have multiple logical bit states facilitating an MLC device. This can be achieved, for instance, by correlating a set of multiple filament states respectively having distinct electrical characteristics (e.g., distinct voltage values, distinct current values, distinct resistance values, and so forth; see, e.g., FIG. 5, infra), with a set of MLC logical bits. This correlation of filament states with MLC logical bits is referred to as a digital information model (though not necessarily a vernacular term used in the industry). The correlation further enables selective programming of memory cell 100A (e.g., to one of the MLC logical bits), by forming a conductive filament having an associated one of the multiple filament states, as mentioned above. Furthermore, by measuring an electrical characteristic of memory cell 100A and comparing the measured result with the distinct electrical characteristics of respective ones of the multiple filament states, a filament state of the conductive filament can be determine. This filament state can then be correlated to an associated MLC logical bit to facilitate reading a program (or erase) state of memory cell 100A.

Various digital information models can be employed to define correlations between the multiple filament states and the MLC logical bits of memory cell 100A. One example model correlates respective subsets of the filament states to respective MLC logical bits. For instance, a positive integer Y of MLC logical bits can be given by 2^{X}, where X is a number of filament states which can be reliably and repeatably formed among multiple memory cells 100A (e.g., an array of memory cells 100A utilized in a memory device). Thus, in this example model, two filament states provide one logical bit, four filament states provide two logical bits, eight filament states provide three logical bits, and so on. In another example digital model, a set of filament states can correspond to a number of MLC logical bits−1, for instance where Y=X−1. In this case, a first filament state can correspond to an erase state, a second filament state can correspond to a first MLC logical bit, a third filament state can correspond to a second MLC logical bit, a fourth filament state can correspond to a third MLC logical bit, and so forth. It should be appreciated that memory cell 100A will generally use only a single digital information model to correlate filament states to MLC logical bits. However, in addition to the foregoing models, other suitable models for correlating a set of filament states to a corresponding set of MLC logical bits can be employed as well.

FIG. 1B illustrates an example memory cell 100B according to additional aspects of the subject disclosure. Memory cell 100B comprises a conductive ion layer 102B adjacent to a resistive ion migration layer 104B. A diode component 106B can be adjacent to resistive ion migration layer 104B. Conductive ion layer 102B can form a first terminal of memory cell 100B, whereas diode component 106B can form, or be adjacent to, a second terminal of memory cell 100B. In at least one embodiment, a bottom layer of memory cell 100B or memory cell 100A can be formed above a substrate of a semiconductor device (e.g., on a suitable Silicon semiconductor material, a suitable Silicon compound, or the like). Accordingly, for memory cell 100B, diode component 106B can be formed on a semiconductor substrate, followed by resistive ion migration layer 104B and conductive ion layer 102B. Conversely, for memory cell 100A, conductive ion layer 106A can be formed on the semiconductor substrate, resistive ion migration layer 104A formed above conductive ion layer 106A, and diode component 102A can be formed above resistive ion migration layer 104A. In one or more embodiments, conductive ion layer 106A can form a second (e.g., bottom) terminal of memory cell 100A, whereas a first terminal can be connected to or adjacent to diode component 102A.

In one or more embodiments of the subject disclosure, memory cell 100A or memory cell 100B can be arranged in one or more memory array configurations. In some embodiments, memory cell 100A or memory cell 100B can be disposed in a two-dimensional array, in which a plurality of memory cells 100A, 100B are arranged into a plurality of rows and columns of such memory cells. In other embodiments, memory cell 100A or memory cell 100B can be disposed in a stacked array, in which multiple memory cells 100A, 100B are stacked one above another, yet individually selectable or addressable. In the latter embodiments, memory cells 100A, 100B can be formed with a low temperature process (e.g., a low temperature deposition process) so that sequential formation of memory cells above or below other memory cells has little or no operational impact on these previously formed, other memory cells. In at least one embodiment, memory cells 100A, 100B can be disposed in a three-dimensional arrangement, comprising a plurality of two-dimensional arrays (respectively comprising columns and rows of memory cells 100A, 100B) stacked into a third dimension, for instance by iterative low temperature deposition processes creating respective ones of the two-dimensional arrays in the third dimension.

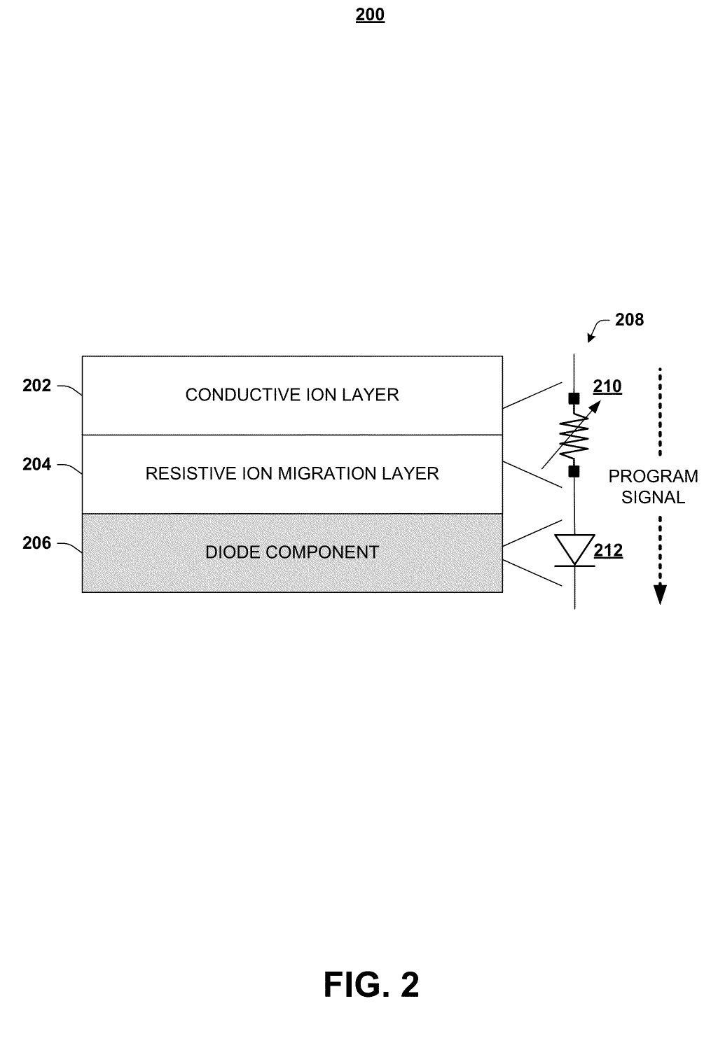

FIG. 2 illustrates a block diagram of an example memory cell 200 according to additional aspects of the subject disclosure. In some embodiments, memory cell 200 can be substantially similar to memory cell 100A of FIG. 1, supra. However, the subject disclosure is not so limited, as in other embodiments memory cell 200 can differ from memory cell 100A in whole or in part.

As depicted, memory cell 200 can comprise a conductive ion layer 202, a resistive ion migration layer 204 and a diode component 206. Prior to programming, resistive ion migration layer 204 can have a high electrical resistance (e.g., 10⁶ ohms or higher). In some embodiments, for instance where resistive ion migration layer 204 is formed of a suitable amorphous silicon material, the electrical resistance can be as high as 10¹⁰ or 10¹¹ ohms, or more. However, the subject disclosure is not limited to these embodiments, and resistive ion migration layer 204 can comprise other suitable materials having high resistance and at least in part permeability to ions of conductive ion layer 202.

The inventors of the subject application understand that conventional materials for memory cells are often not suitable for MLC characteristics. For instance, the inventors are aware that some two-terminal memory cells have been proposed utilizing crystalline-based oxides (e.g., silicon-oxide, and so forth) as a resistive-switching medium for a resistive switching memory device. However, crystalline oxides tend to experience a breakdown phenomenon in response to application of a suitable signal for forming a conductive filament. The inventors believe that this breakdown may occur from joule heating as part of an ion injection process that breaks silicon-based bonds of the crystalline-based oxide resistive-switching medium. The result is that filament formation is not a well controlled process suitable for achieving a selected one of multiple filament states. Memory cell 200, however, can comprise a resistive ion migration layer 204 that is at least in part permeably to ions of conductive ion layer 202. Accordingly, ions can migrate into resistive ion migration layer 204 without breaking bonds, in a conductive filament formation process that can be controlled. For example, the process can be controlled by selected a predetermined set of signal characteristics of a program signal utilized to form the conductive filament. The predetermined set of signal characteristics can include, for instance, a selected current magnitude, a selected program voltage, a selected program pulse width, or the like, or a suitable combination thereof. This allows for predictability in creating a conductive filament having a selected one of a set of filament states, and therefore a selected one of a set of MLC logical bits.

In operation, a suitable program signal having one of a set of signal characteristics can be applied to memory cell 200. This program signal results in formation of a conductive filament having a selected one of a set of filament states (e.g., see FIG. 5, infra, for illustration). This migration of ions can reduce electrical characteristics of ion migration layer 204 and memory 200 (e.g., resistance, conductivity, etc.) in a measurable and predetermined manner. Accordingly, memory cell 200 can be reliably programmed to one of a set of MLC logical bits, represented by the one of the set of filament states.

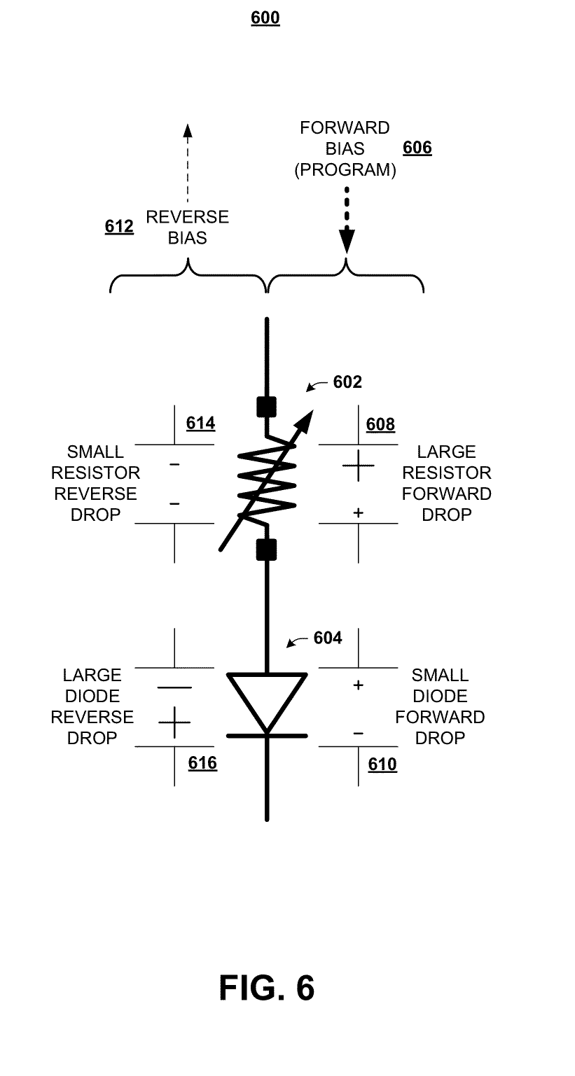

In addition to the foregoing, diode component 206 can have a reverse bias polarity opposite a polarity of a suitable program signal for memory cell 200. Because of the ion permeability of resistive ion migration layer 204, a reverse bias polarity could ordinarily cause ions to migrate toward conductive ion layer 202, increasing electrical resistance of resistive ion migration layer 204. To mitigate or prevent deformation of a conductive filament formed within ion migration layer 204, diode component 206 can be configured to have a reverse bias breakdown voltage that is greater in magnitude than an erase voltage suitable to deform the conductive filament. In addition, diode component 206 can be configured to have a reverse bias current much smaller than that suitable for deforming the conductive filament. Accordingly, a reverse bias voltage applied to memory cell 200 will drop in greatest part at diode component 206 (e.g., see FIG. 6, infra), avoiding a suitable erase voltage magnitude from occurring at resistive ion migration layer 204 in response to the reverse bias voltage. Accordingly, memory cell 200 can operate as an OTP memory cell, allowing selective programming of one of a set of MLC logical bits (e.g., based on a suitable set of program signal characteristics), while mitigating or preventing erasure of the programming.

Memory cell 200 is depicted schematically by circuit diagram 208. A switchable resistor 210 can comprise conductive ion layer 202 and resistive ion migration layer 204. Switchable resistor 210 can be programmed to have one of a set of resistance states, including an “off”, or non-programmed resistance (e.g., very high resistance), and multiple “on” or program resistances, each of which are measurably distinct. Diode 212 corresponds with diode component 206, and operates to resist current flow in an opposite direction as a program signal (dotted arrow) suitable for programming memory cell 200.

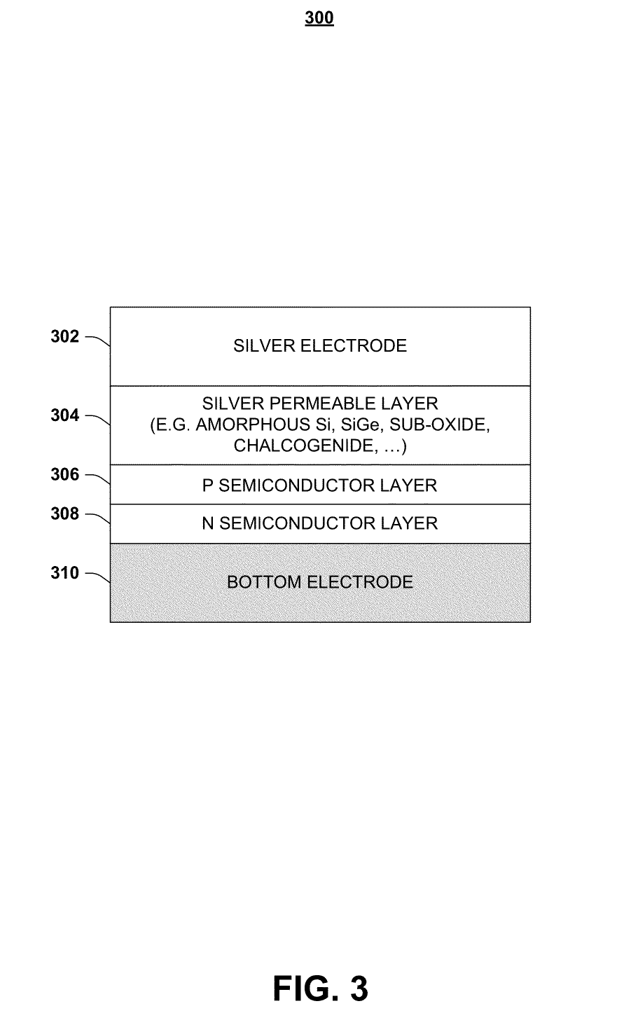

FIG. 3 depicts a block diagram of an example memory cell 300 according to one or more embodiments of the subject disclosure. Memory cell 300 can be configured as a two-terminal memory cell, operable (e.g., programmable, programmable to one of a set of logical bits, and so forth) in response to a suitable program signal(s) applied across the two terminals. As depicted, memory cell 300 can comprise a silver electrode 302. Silver electrode 302 can serve as a first of the two terminals of memory cell 300. In one example, silver electrode 302 can serve as a top electrode for memory cell 300 (e.g., connected to a bitline of a memory device), whereas in other examples silver electrode 302 can serve as a bottom electrode for memory cell 300 (e.g., connected to a dataline, a wordline, a semiconductor substrate, or the like, as suitable for a desired memory architecture).

Adjacent to silver electrode 302, memory cell 300 can comprise a silver permeable layer 304. Silver permeably layer 304 can comprise a suitable high resistance material within which silver ions can move in response to an electromotive force. Particularly, the material can facilitate mobility of the silver ions without a breakdown of the high resistance material. Accordingly, permeation of silver ions within silver permeable layer 304 can be relatively controllable in response to a suitable signal. Thus, a suitable program signal applied to memory cell 300 can form a conductive filament of silver ions within silver permeable layer 304, having a selected of a set of filament states. This can facilitate MLC programming, as described herein.

In at least one embodiment, an additional layer can be formed between silver electrode layer 302 and silver permeable layer 304. This additional layer can be resistant to oxidation, mitigating oxidation damage to regions of silver permeable layer 304 or silver electrode layer 302 adjacent to the additional layer. Examples of the additional layer can include, for instance, a titanium layer, or other material to facilitate mitigation of oxidation.

Further to the above, memory cell 300 can comprise a p semiconductor layer 306 adjacent to an n semiconductor layer 308. In at least one disclosed embodiment, memory cell 300 can have the respective positions of p semiconductor layer 306 and n semiconductor layer 308 switched (e.g., with n semiconductor layer 308 adjacent to silver permeable layer 304). The combination of p semiconductor layer 306 and n semiconductor layer 308 can form a diode component that resists electrical current in a reverse bias direction, which flows from a bottom electrode 310 of memory cell 300 to silver electrode 302. P semiconductor layer 306 or n semiconductor layer 308 can be of suitable dimension(s), suitable doping (if any), or otherwise configured to have a reverse bias current that is smaller than a current magnitude required to deform a conductive filament of silver ions within silver permeable layer 304. Accordingly, the diode component of p semiconductor layer 306 and n semiconductor layer 308 can be configured to mitigate or avoid erasing of a programmed conductive filament of memory cell 300, facilitating OTP memory operation.

Bottom electrode 310 can be a suitable electrical conductor. Examples include metals, conductively doped silicon or silicon compounds, or the like. In some embodiments, bottom electrode 310 can be formed on a semiconductor substrate. Accordingly, memory cell 300 can be compatible with at least some silicon-based semiconductor fabrication techniques. In addition to the foregoing, memory cell 300 can be organized into an array of such memory cells 300 to form a two-dimensional memory array. In a further embodiment, multiple two-dimensions arrays of memory cells 300 can be stacked in a third dimension, to facilitate a three dimensional array of memory cells 300. This can serve to provide very high memory densities for solid state memory applications, coupled with a high read speed anticipated by the inventors for the resistive-switching two-terminal memory cell structure of memory cell 300.

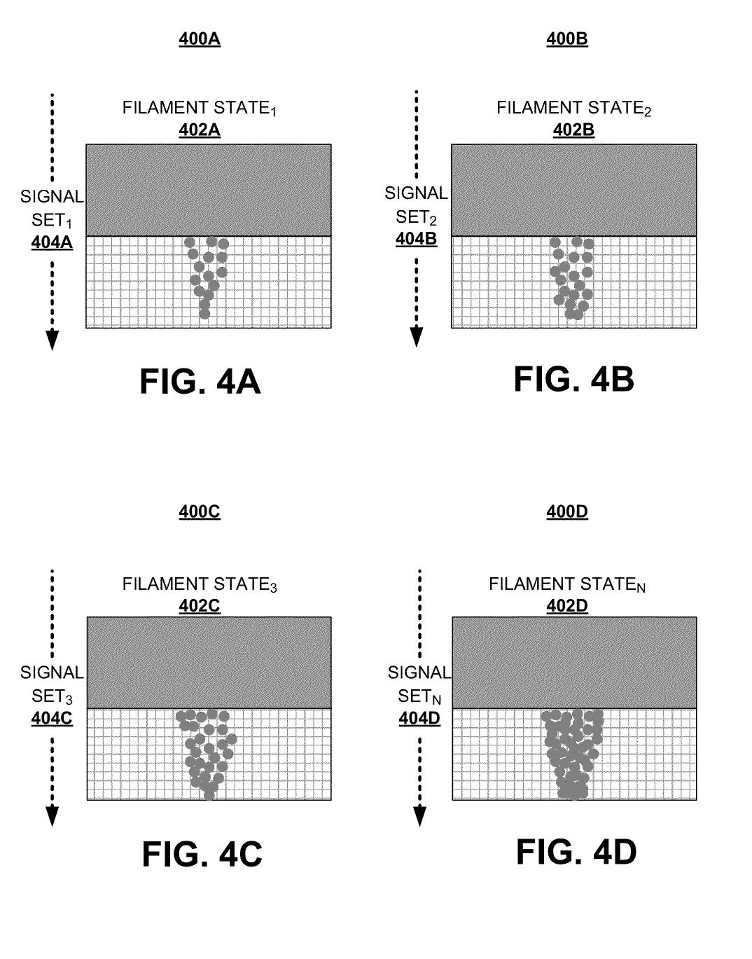

FIGS. 4A-4D illustrates respective diagrams 400A-400D of example conductive filament states for a MLC memory cell according to additional embodiments of the subject disclosure. Diagram 400A illustrates a first filament state, filament state₁ 402A. Filament state₁ 402A can be comprised of ions from a conductive layer (dark shading) within a resistive ion migration layer (cross-hatch shading), in response to a program signal have a first set of signal characteristics₁ 404A. Set of signal characteristics₁ 404A can be comprised of a current magnitude, voltage magnitude, program signal pulse width, or the like, or a suitable combination thereof, configured to produce a conductive filament having filament state₁ 402A. Moreover, filament state₁ 402A can cause resistive ion migration layer of diagram 400A to have a first set of distinct and measurable electrical characteristics. Likewise, diagram 400B illustrates a second filament state₂ 402B formed in response to a program signal having a second set of signal characteristics₂ 404B, distinct from set of signal characteristics₁ 404A. Second filament state₂ 402B can have a second set of distinct and measurable electrical characteristics, different from the first set of electrical characteristics of filament state₁ 402A. For instance, the second set of electrical characteristics can correspond to a lower resistance than the first set of electrical characteristics. Moreover, diagrams 400C and 400D have corresponding filament states 402C, 402D formed in resistive ion migration layer in response to respective program signals having a third set of signal characteristics₃ 404C and an N^{th} set of signal characteristics_{N} 404D.

FIG. 5 illustrates a diagram of an example set of filament states 500 within an ion migration layer 502 of a MLC OTP memory cell in additional aspects of the subject disclosure. Depicted filament states 504 can be formed to induce distinct electrical characteristics for the MLC OTP memory cell, which can be measured to determine an electrical state thereof. For instance, respective filament states S₁ 506, S₂ 508, S₃ 510, S₄ 512 (referred to collectively as filament states 506-512) can induce respective resistances (or respective ranges of resistances) in the MLC OTP memory cell. By measuring the resistance of the memory cell, a program state of the memory cell can also be inferred.

As described herein, ion migration layer 502 can comprise a suitable material enabling propagation of ions within ion migration layer 502. Respective filament states 506-512 are formed within ion migration layer 502 in response to respective suitable program signals (e.g., as described with respect to FIG. 4, supra). By selecting one of the suitable program signals, a corresponding one of filament states 506-512 can be formed within ion migration layer 502. This property of the MLC OTP memory cell can facilitate reliable programming of one of multiple MLC logical bits. Although not depicted, a diode component can be included to mitigate or avoid erasure of the programming. Accordingly, the memory cell can retain the programmed logical bit, and can be read (e.g., measured) to extract information stored by the memory cell. Arrays of the MLC OTP memory cell can be formed to facilitate storage of many logical bits of information, as is known in the art. Multiple arrays of such memory cells can be stacked in a third dimension to facilitate higher density memory devices, facilitating more efficient memory storage according to alternative or additional embodiments of the subject disclosure.

FIG. 6 illustrates a schematic diagram of an example MLC OTP memory cell 600 according to additional aspects of the subject disclosure. The schematic diagram further illustrates response of MLC OTP memory cell 600 to a program signal having a forward bias, and to a reverse bias signal. As depicted, MLC OTP memory cell 600 can be programmed to one of a set of logical bits, while mitigating or avoiding erasure of the programmed logical bit.

MLC OTP memory cell 600 can comprise a resistive-switching component 602 in electrical series with a diode component 604. A forward bias (e.g., program signal) 606 applied to MLC OTP memory cell 600 can result in a large resistor voltage drop 608 across resistive-switching component 602, and a smaller diode voltage drop 610 across diode component 604. Accordingly, resistive-switching component 602 is the current limiting component of MLC OTP memory cell 600 with respect to forward bias 606. The large resistor voltage drop 608 can be configured at least in part to cause a selected one of multiple program states of resistive-switching component 602. In alternative or additional aspects, a magnitude of the voltage drop, a current magnitude or a pulse width of the program signal, or a suitable combination thereof, can be selected to cause the selected one of multiple program states to be programmed to resistive-switching component 602.

In response to a reverse bias 612, a large diode voltage drop 616 occurs across diode component 604. A much smaller resistor voltage drop 614 is observed across resistive-switching component 602 with respect to reverse bias 612. Diode component 604 and resistive-switching component 602 can be configured such that the smaller resistive voltage drop 614 is smaller than required to erase resistive-switching component 602 (e.g., to deform a filament corresponding to a selected one of the multiple program states). Accordingly, diode component 604 acts as the current limiting component of MLC OTP memory cell 600 with respect to reverse bias 612. This enables MLC OTP memory cell 600 to resist or avoid erasure of a programmed state of resistive-switching component 602, providing OTP characteristics for MLC OTP memory cell 600.

The aforementioned diagrams have been described with respect to interaction between several components of a memory cell, memory arrays, or memory architectures comprised of such memory cells. It should be appreciated that in some suitable alternative aspects of the subject disclosure, such diagrams can include those components and architectures specified therein, some of the specified components/architectures, or additional components/architectures. Sub-components can also be implemented as electrically connected to other sub-components rather than included within a parent architecture. Additionally, it is noted that one or more disclosed processes can be combined into a single process providing aggregate functionality. For instance, a deposition process can comprise a fill or etching process, an anneal process, or the like, or vice versa, to facilitate deposition, filling or etching of memory cell layers by way of an aggregate process. Components of the disclosed architectures can also interact with one or more other components not specifically described herein but known by those of skill in the art.

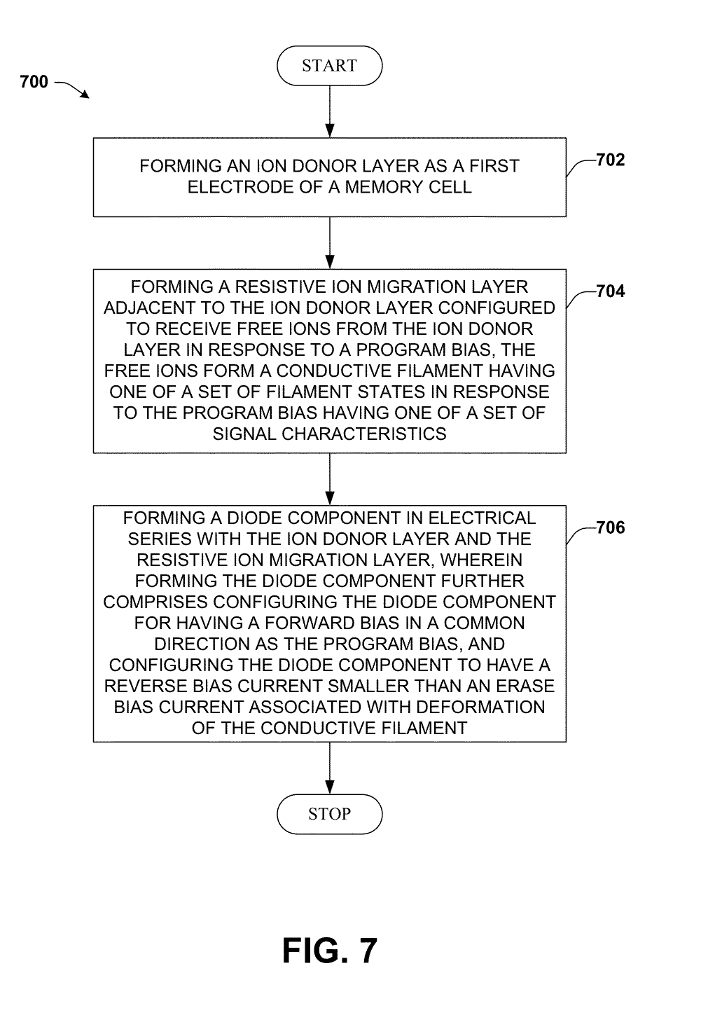

In view of the exemplary diagrams described supra, a process method that can be implemented in accordance with the disclosed subject matter will be better appreciated with reference to the flow chart of FIG. 7. While for purposes of simplicity of explanation, the method of FIG. 7 is shown and described as a series of blocks, it is to be understood and appreciated that the claimed subject matter is not limited by the order of the blocks, as some blocks may occur in different orders or concurrently with other blocks from what is depicted and described herein. Moreover, not all illustrated blocks may be required to implement the method described herein. Additionally, it should be further appreciated that the method is capable of being stored on an article of manufacture to facilitate transporting and transferring such method to an electronic device. The term article of manufacture, as used, is intended to encompass a computer program accessible from any suitable computer-readable device, device in conjunction with a carrier, storage medium, or the like, or a suitable combination thereof.

FIG. 7 illustrates a flowchart of a sample method 700 for fabricating a memory cell according to additional embodiments of the subject disclosure. At 702, method 700 can comprise forming an ion donor layer as a first electrode of a memory cell. The ion donor layer can comprise a material having free ions (e.g., electrons, holes). Examples can include Ag, Au, Ti, Ni, Cu, Al, Cr, Ta, Fe, Mn, W, V, Co, Pt, or Pd, or the like, or a suitable compound of the foregoing. At 704, method 700 can comprise forming a resistive ion migration layer adjacent to the ion donor layer configured to receive free ions from the ion donor layer in response to a program bias applied to the memory cell. In various embodiments, the free ions can form a conductive filament having one of a set of filament states in response to the program bias having a corresponding one of a set of signal characteristics. Furthermore, at 706, method 700 can comprise forming a diode component in electrical series with the ion donor layer and the resistive ion migration layer. Forming the diode component can further comprise configuring the diode component for having a forward bias in a common direction as the program bias, and to have a reverse bias current smaller than an erase bias current associated with deformation of the conductive filament.

In an additional embodiment, method 700 can comprise forming a second electrode of the memory cell adjacent to the diode component. The second electrode can be a suitable conductor, such as a metal, a conductively doped semiconductor material (e.g., silicon) or the like. In another embodiment, method 700 can comprise forming an oxide layer that is permeable to the free ions between the resistive ion migration layer and the diode component. The oxide layer can mitigate or avoid oxidation of the resistive ion migration layer. In at least one other embodiment, forming the diode component can further comprise forming a p semiconductor layer adjacent to an n semiconductor layer, such that the combination of the p semiconductor layer and the n semiconductor layer have the forward bias in the common direction as the program bias, and the reverse bias current is smaller than the erase bias current. According to this configuration, the memory cell can mitigate erasing of the memory cell, facilitating OTP characteristics of the memory cell.

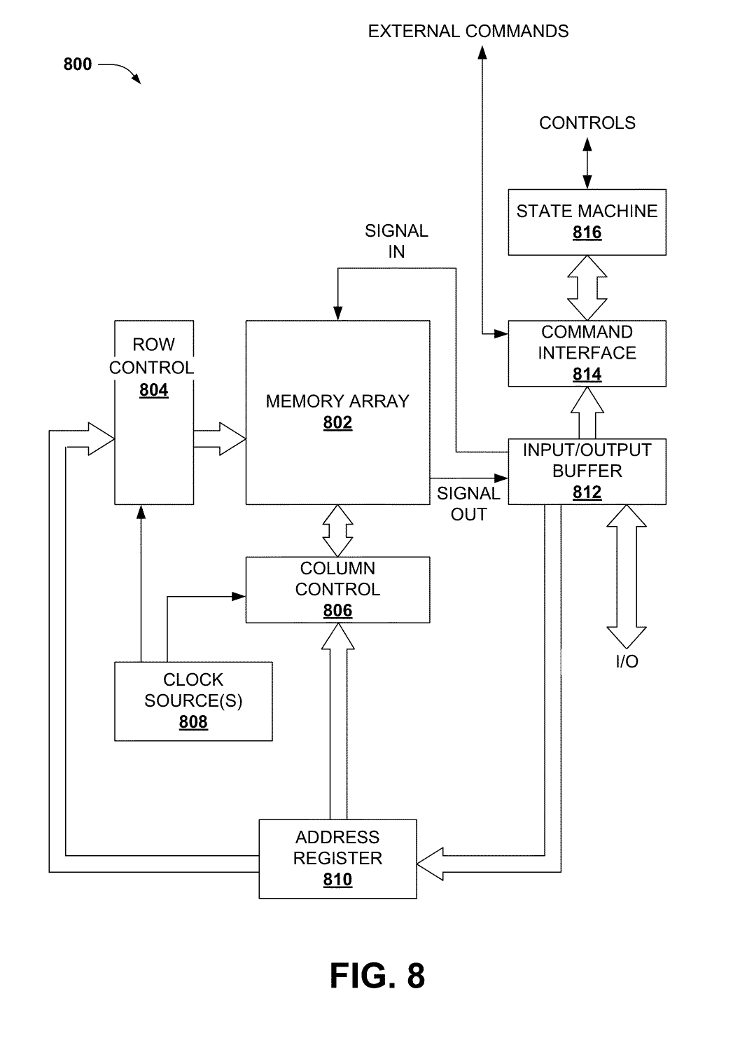

In order to provide a context for the various aspects of the disclosed subject matter, FIG. 8, as well as the following discussion, is intended to provide a brief, general description of a suitable environment in which various aspects of the disclosed subject matter can be implemented or processed. While the subject matter has been described above in the general context of semiconductor architectures and process methods for fabricating or operating such architectures, those skilled in the art will recognize that the subject disclosure also can be implemented in combination with other architectures or process methods. Moreover, those skilled in the art will appreciate that the disclosed processes can be implemented within a processing system or a computer processor, either alone or in conjunction with a host computer, which can include single-processor or multiprocessor computer systems, mini-computing devices, mainframe computers, as well as personal computers, hand-held computing devices (e.g., PDA, smart phone, watch), microprocessor-based or programmable consumer or industrial electronics, and the like. The illustrated aspects may also be practiced in distributed computing environments where tasks are performed by remote processing devices that are linked through a communications network. However, some, if not all aspects of the claimed innovation can be practiced on stand-alone electronic devices, such as a memory card, FLASH memory module, removable memory, or the like. In a distributed computing environment, program modules can be located in both local and remote memory storage modules or devices.

FIG. 8 illustrates a block diagram of an example operating and control environment 800 for a memory cell array 802 according to aspects of the subject disclosure. In at least one aspect of the subject disclosure, memory cell array 802 can comprise a variety of memory cell technology. Particularly, memory cell array 802 can comprise two-terminal memory such as resistive-switching memory cells. In various embodiments, memory cell array 802 can be a NAND array comprising two-terminal memory. In at least one embodiment, memory cell array 802 can be a NAND array having respective memory cells that comprise a 1T-1D parallel circuit, as described herein.

A column controller 806 can be formed adjacent to memory cell array 802. Moreover, column controller 806 can be electrically coupled with bit lines of memory cell array 802. Column controller 806 can control respective bitlines, applying suitable program, erase or read voltages to selected bitlines.

In addition, operating and control environment 800 can comprise a row controller 804. Row controller 804 can be formed adjacent to column controller 806, and electrically connected with word lines of memory cell array 802. Row controller 804 can select particular rows of memory cells with a suitable selection voltage. Moreover, row controller 804 can facilitate program, erase or read operations by applying suitable voltages at selected word lines.

A clock source(s) 808 can provide respective clock pulses to facilitate timing for read, write, and program operations of row control 804 and column control 806. Clock source(s) 808 can further facilitate selection of word lines or bit lines in response to external or internal commands received by operating and control environment 800. An input/output buffer 812 can be connected to an external host apparatus, such as a computer or other processing device (not depicted) by way of an I/O buffer or other I/O communication interface. Input/output buffer 812 can be configured to receive write data, receive an erase instruction, output readout data, and receive address data and command data, as well as address data for respective instructions. Address data can be transferred to row controller 804 and column controller 806 by an address register 810. In addition, input data is transmitted to memory cell array 802 via signal input lines, and output data is received from memory cell array 802 via signal output lines. Input data can be received from the host apparatus, and output data can be delivered to the host apparatus via the I/O buffer.

Commands received from the host apparatus can be provided to a command interface 814. Command interface 814 can be configured to receive external control signals from the host apparatus, and determine whether data input to the input/output buffer 812 is write data, a command, or an address. Input commands can be transferred to a state machine 816.

State machine 816 can be configured to manage programming and reprogramming of memory cell array 802. State machine 816 receives commands from the host apparatus via input/output interface 812 and command interface 814, and manages read, write, erase, data input, data output, and like functionality associated with memory cell array 802. In some aspects, state machine 816 can send and receive acknowledgments and negative acknowledgments regarding successful receipt or execution of various commands.

To implement read, write, erase, input, output, etc., functionality, state machine 816 can control clock source(s) 808. Control of clock source(s) 808 can cause output pulses configured to facilitate row controller 804 and column controller 806 implementing the particular functionality. Output pulses can be transferred to selected bit lines by column controller 806, for instance, or word lines by row controller 804, for instance.

The illustrated aspects of the disclosure may also be practiced in distributed computing environments where certain tasks are performed by remote processing devices that are linked through a communications network. In a distributed computing environment, program modules or stored information, instructions, or the like can be located in local or remote memory storage devices.

Moreover, it is to be appreciated that various components described herein can include electrical circuit(s) that can include components and circuitry elements of suitable value in order to implement the embodiments of the subject innovation(s). Furthermore, it can be appreciated that many of the various components can be implemented on one or more IC chips. For example, in one embodiment, a set of components can be implemented in a single IC chip. In other embodiments, one or more respective components are fabricated or implemented on separate IC chips.

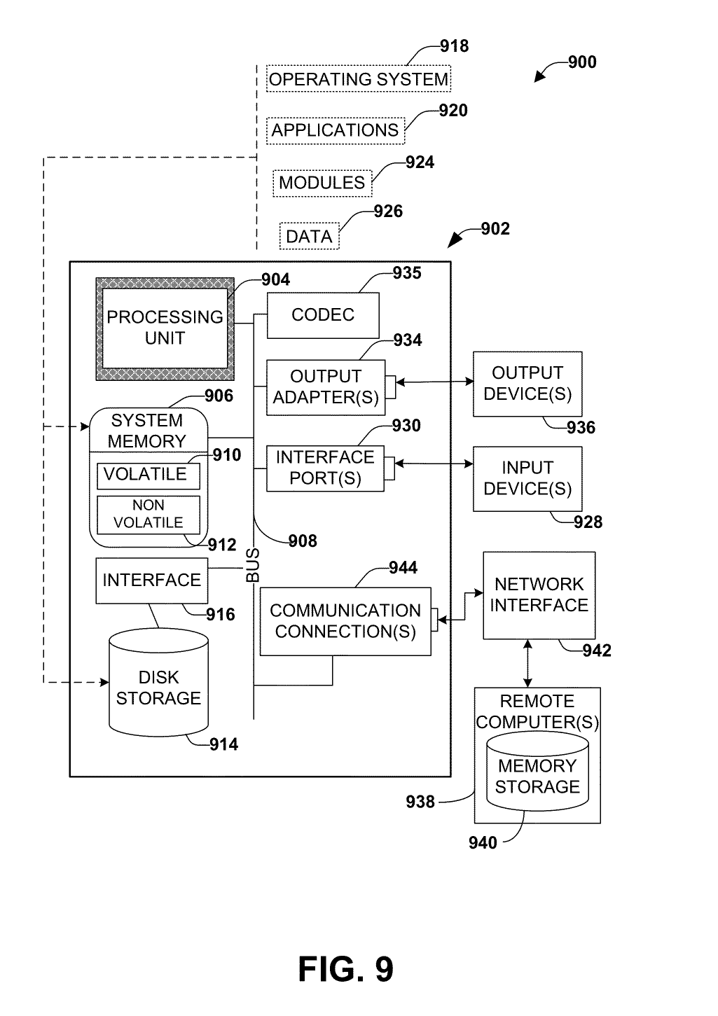

In connection with FIG. 9, the systems and processes described below can be embodied within hardware, such as a single integrated circuit (IC) chip, multiple ICs, an application specific integrated circuit (ASIC), or the like. Further, the order in which some or all of the process blocks appear in each process should not be deemed limiting. Rather, it should be understood that some of the process blocks can be executed in a variety of orders, not all of which may be explicitly illustrated herein.

With reference to FIG. 9, a suitable environment 900 for implementing various aspects of the claimed subject matter includes a computer 902. The computer 902 includes a processing unit 904, a system memory 906, a codec 935, and a system bus 908. The system bus 908 couples system components including, but not limited to, the system memory 906 to the processing unit 904. The processing unit 904 can be any of various available processors. Dual microprocessors and other multiprocessor architectures also can be employed as the processing unit 904.

The system bus 908 can be any of several types of bus structure(s) including the memory bus or memory controller, a peripheral bus or external bus, and/or a local bus using any variety of available bus architectures including, but not limited to, Industrial Standard Architecture (ISA), Micro-Channel Architecture (MSA), Extended ISA (EISA), Intelligent Drive Electronics (IDE), VESA Local Bus (VLB), Peripheral Component Interconnect (PCI), Card Bus, Universal Serial Bus (USB), Advanced Graphics Port (AGP), Personal Computer Memory Card International Association bus (PCMCIA), Firewire (IEEE 1394), and Small Computer Systems Interface (SCSI).

The system memory 906 includes volatile memory 910 and non-volatile memory 912. The basic input/output system (BIOS), containing the basic routines to transfer information between elements within the computer 902, such as during start-up, is stored in non-volatile memory 912. In addition, according to present innovations, codec 935 may include at least one of an encoder or decoder, wherein the at least one of an encoder or decoder may consist of hardware, software, or a combination of hardware and software. Although, codec 935 is depicted as a separate component, codec 935 may be contained within non-volatile memory 912. By way of illustration, and not limitation, non-volatile memory 912 can include read only memory (ROM), programmable ROM (PROM), electrically programmable ROM (EPROM), electrically erasable programmable ROM (EEPROM), or flash memory. Volatile memory 910 includes random access memory (RAM), which acts as external cache memory. According to present aspects, the volatile memory may store the write operation retry logic (not shown in FIG. 9) and the like. By way of illustration and not limitation, RAM is available in many forms such as static RAM (SRAM), dynamic RAM (DRAM), synchronous DRAM (SDRAM), double data rate SDRAM (DDR SDRAM), and enhanced SDRAM (ESDRAM).

Computer 902 may also include removable/non-removable, volatile/non-volatile computer storage medium. FIG. 9 illustrates, for example, disk storage 914. Disk storage 914 includes, but is not limited to, devices like a magnetic disk drive, solid state disk (SSD) floppy disk drive, tape drive, Jaz drive, Zip drive, LS-100 drive, flash memory card, or memory stick. In addition, disk storage 914 can include storage medium separately or in combination with other storage medium including, but not limited to, an optical disk drive such as a compact disk ROM device (CD-ROM), CD recordable drive (CD-R Drive), CD rewritable drive (CD-RW Drive) or a digital versatile disk ROM drive (DVD-ROM). To facilitate connection of the disk storage devices 914 to the system bus 908, a removable or non-removable interface is typically used, such as interface 916. It is appreciated that storage devices 914 can store information related to a user. Such information might be stored at or provided to a server or to an application running on a user device. In one embodiment, the user can be notified (e.g., by way of output device(s) 936) of the types of information that are stored to disk storage 914 and/or transmitted to the server or application. The user can be provided the opportunity to opt-in or opt-out of having such information collected and/or shared with the server or application (e.g., by way of input from input device(s) 928).

It is to be appreciated that FIG. 9 describes software that acts as an intermediary between users and the basic computer resources described in the suitable operating environment 900. Such software includes an operating system 918. Operating system 918, which can be stored on disk storage 914, acts to control and allocate resources of the computer system 902. Applications 920 take advantage of the management of resources by operating system 918 through program modules 924, and program data 926, such as the boot/shutdown transaction table and the like, stored either in system memory 906 or on disk storage 914. It is to be appreciated that the claimed subject matter can be implemented with various operating systems or combinations of operating systems.

A user enters commands or information into the computer 902 through input device(s) 928. Input devices 928 include, but are not limited to, a pointing device such as a mouse, trackball, stylus, touch pad, keyboard, microphone, joystick, game pad, satellite dish, scanner, TV tuner card, digital camera, digital video camera, web camera, and the like. These and other input devices connect to the processing unit 904 through the system bus 908 via interface port(s) 930. Interface port(s) 930 include, for example, a serial port, a parallel port, a game port, and a universal serial bus (USB). Output device(s) 936 use some of the same type of ports as input device(s) 928. Thus, for example, a USB port may be used to provide input to computer 902 and to output information from computer 902 to an output device 936. Output adapter 934 is provided to illustrate that there are some output devices 936 like monitors, speakers, and printers, among other output devices 936, which require special adapters. The output adapters 934 include, by way of illustration and not limitation, video and sound cards that provide a means of connection between the output device 936 and the system bus 908. It should be noted that other devices and/or systems of devices provide both input and output capabilities such as remote computer(s) 938.

Computer 902 can operate in a networked environment using logical connections to one or more remote computers, such as remote computer(s) 938. The remote computer(s) 938 can be a personal computer, a server, a router, a network PC, a workstation, a microprocessor based appliance, a peer device, a smart phone, a tablet, or other network node, and typically includes many of the elements described relative to computer 902. For purposes of brevity, only a memory storage device 940 is illustrated with remote computer(s) 938. Remote computer(s) 938 is logically connected to computer 902 through a network interface 942 and then connected via communication connection(s) 944. Network interface 942 encompasses wire and/or wireless communication networks such as local-area networks (LAN) and wide-area networks (WAN) and cellular networks. LAN technologies include Fiber Distributed Data Interface (FDDI), Copper Distributed Data Interface (CDDI), Ethernet, Token Ring and the like. WAN technologies include, but are not limited to, point-to-point links, circuit switching networks like Integrated Services Digital Networks (ISDN) and variations thereon, packet switching networks, and Digital Subscriber Lines (DSL).

Communication connection(s) 944 refers to the hardware/software employed to connect the network interface 942 to the bus 908. While communication connection 944 is shown for illustrative clarity inside computer 902, it can also be external to computer 902. The hardware/software necessary for connection to the network interface 942 includes, for exemplary purposes only, internal and external technologies such as, modems including regular telephone grade modems, cable modems and DSL modems, ISDN adapters, and wired and wireless Ethernet cards, hubs, and routers.

As utilized herein, terms “component,” “system,” “architecture” and the like are intended to refer to a computer or electronic-related entity, either hardware, a combination of hardware and software, software (e.g., in execution), or firmware. For example, a component can be one or more transistors, a memory cell, an arrangement of transistors or memory cells, a gate array, a programmable gate array, an application specific integrated circuit, a controller, a processor, a process running on the processor, an object, executable, program or application accessing or interfacing with semiconductor memory, a computer, or the like, or a suitable combination thereof. The component can include erasable programming (e.g., process instructions at least in part stored in erasable memory) or hard programming (e.g., process instructions burned into non-erasable memory at manufacture).

By way of illustration, both a process executed from memory and the processor can be a component. As another example, an architecture can include an arrangement of electronic hardware (e.g., parallel or serial transistors), processing instructions and a processor, which implement the processing instructions in a manner suitable to the arrangement of electronic hardware. In addition, an architecture can include a single component (e.g., a transistor, a gate array, and so forth) or an arrangement of components (e.g., a series or parallel arrangement of transistors, a gate array connected with program circuitry, power leads, electrical ground, input signal lines and output signal lines, and so on). A system can include one or more components as well as one or more architectures. One example system can include a switching block architecture comprising crossed input/output lines and pass gate transistors, as well as power source(s), signal generator(s), communication bus(ses), controllers, I/O interface, address registers, and so on. It is to be appreciated that some overlap in definitions is anticipated, and an architecture or a system can be a stand-alone component, or a component of another architecture, system, etc.

In addition to the foregoing, the disclosed subject matter can be implemented as a method, apparatus, or article of manufacture using typical manufacturing, programming or engineering techniques to produce hardware, firmware, software, or any suitable combination thereof to control an electronic device to implement the disclosed subject matter. The terms “apparatus” and “article of manufacture” where used herein are intended to encompass an electronic device, a semiconductor device, a computer, or a computer program accessible from any computer-readable device, carrier, or media. Computer-readable media can include hardware media, or software media. In addition, the media can include non-transitory media, or transport media. In one example, non-transitory media can include computer readable hardware media. Specific examples of computer readable hardware media can include but are not limited to magnetic storage devices (e.g., hard disk, floppy disk, magnetic strips), optical disks (e.g., compact disk (CD), digital versatile disk (DVD)), smart cards, and flash memory devices (e.g., card, stick, key drive). Computer-readable transport media can include carrier waves, or the like. Of course, those skilled in the art will recognize many modifications can be made to this configuration without departing from the scope or spirit of the disclosed subject matter.

What has been described above includes examples of the subject innovation. It is, of course, not possible to describe every conceivable combination of components or methodologies for purposes of describing the subject innovation, but one of ordinary skill in the art can recognize that many further combinations and permutations of the subject innovation are possible. Accordingly, the disclosed subject matter is intended to embrace all such alterations, modifications and variations that fall within the spirit and scope of the disclosure. Furthermore, to the extent that a term “includes”, “including”, “has” or “having” and variants thereof is used in either the detailed description or the claims, such term is intended to be inclusive in a manner similar to the term “comprising” as “comprising” is interpreted when employed as a transitional word in a claim.

Moreover, the word “exemplary” is used herein to mean serving as an example, instance, or illustration. Any aspect or design described herein as “exemplary” is not necessarily to be construed as preferred or advantageous over other aspects or designs. Rather, use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form.

Additionally, some portions of the detailed description have been presented in terms of algorithms or process operations on data bits within electronic memory. These process descriptions or representations are mechanisms employed by those cognizant in the art to effectively convey the substance of their work to others equally skilled. A process is here, generally, conceived to be a self-consistent sequence of acts leading to a desired result. The acts are those requiring physical manipulations of physical quantities. Typically, though not necessarily, these quantities take the form of electrical and/or magnetic signals capable of being stored, transferred, combined, compared, and/or otherwise manipulated.

It has proven convenient, principally for reasons of common usage, to refer to these signals as bits, values, elements, symbols, characters, terms, numbers, or the like. It should be borne in mind, however, that all of these and similar terms are to be associated with the appropriate physical quantities and are merely convenient labels applied to these quantities. Unless specifically stated otherwise or apparent from the foregoing discussion, it is appreciated that throughout the disclosed subject matter, discussions utilizing terms such as processing, computing, replicating, mimicking, determining, or transmitting, and the like, refer to the action and processes of processing systems, and/or similar consumer or industrial electronic devices or machines, that manipulate or transform data or signals represented as physical (electrical or electronic) quantities within the circuits, registers or memories of the electronic device(s), into other data or signals similarly represented as physical quantities within the machine or computer system memories or registers or other such information storage, transmission and/or display devices.

In regard to the various functions performed by the above described components, architectures, circuits, processes and the like, the terms (including a reference to a “means”) used to describe such components are intended to correspond, unless otherwise indicated, to any component which performs the specified function of the described component (e.g., a functional equivalent), even though not structurally equivalent to the disclosed structure, which performs the function in the herein illustrated exemplary aspects of the embodiments. In addition, while a particular feature may have been disclosed with respect to only one of several implementations, such feature may be combined with one or more other features of the other implementations as may be desired and advantageous for any given or particular application. It will also be recognized that the embodiments include a system as well as a computer-readable medium having computer-executable instructions for performing the acts and/or events of the various processes.

What is claimed is:

1. A memory cell, comprising:
an ion donor layer configured to facilitate provision of free ions in response to a program signal applied to the memory cell;
a resistive ion migration layer configured to receive ions from the ion donor layer to facilitate formation of a conductive filament within the resistive ion migration layer in response to the program signal, the conductive filament corresponding to one of a set of plural filament states that characterize the memory cell; and
a diode component configured to facilitate current flow in a forward direction for the memory cell corresponding with ion migration from the ion donor layer to the resistive ion migration layer, and to resist current flow in a reverse direction.

2. The memory cell of claim 1, wherein the memory cell comprises a single diode single resistor (1D-1R) arrangement.

3. The memory cell of claim 1, wherein respective ones of the set of plural filament states correspond with respective ones of a set of logical states.

4. The memory cell of claim 3, wherein the respective ones of the set of plural filament states correspond with a set of distinct electrical characteristics of the memory cell, the set of distinct electrical characteristics indicative of the respective ones of the set of logical states.

5. The memory cell of claim 1, wherein the conductive filament forms the one of the set of plural filament states in response to the program signal having one of a set of signal characteristics.

6. The memory cell of claim 5, wherein the set of signal characteristics comprises a current value of a set of current values, wherein respective ones of the set of current values correspond at least in part to respective ones of the set of plural filament states.

7. The memory cell of claim 5, wherein the set of signal characteristics comprises a voltage value of a set of voltage values, wherein respective ones of the set of voltage values correspond at least in part to respective ones of the set of plural filament states.

8. The memory cell of claim 5, wherein the set of signal characteristics comprises a program signal time pulse of a set of time pulses for the program signal, wherein respective ones of the set of time pulses correspond at least in part to respective ones of the set of plural filament states.

9. The memory cell of claim 5, wherein the set of signal characteristics comprises one or more of a current value, a voltage value or a time pulse that corresponds to creation of the conductive filament within the resistive ion migration layer from free ions of the ion donor layer, having the one of the set of plural filament states.

10. The memory cell of claim 1, wherein the ion donor layer and the resistive ion migration layer form a bipolar resistive memory cell configured to facilitate formation of the conductive filament in response to the program signal having a positive bias, and configured for deformation of the conductive filament in response to a signal having a negative bias of a deformation magnitude, and further wherein the diode component has a reverse diode breakdown voltage larger than the deformation magnitude, or a reverse bias current smaller than an erase current of the bipolar resistive memory cell.

11. The memory cell of claim 1, wherein the memory cell is a one time programmable multi-level cell configured to be programmed to a selected bit of a set of multiple logical bits and configured to mitigate erasure of the selected bit.

12. The memory cell of claim 11, wherein the set of multiple logical bits enables the memory cell to be programmed to one of two logical bits, one of three logical bits or one of four logical bits.

13. The memory cell of claim 1, wherein the resistive ion migration layer is formed of silicon, an amorphous silicon, a silicon-oxygen compound, a silicon-germanium compound, an oxide or a chalcogenide.

14. The memory cell of claim 1, wherein the memory cell is formed above or below a second one of the memory cell via a low temperature deposition process.

15. A method of fabricating a memory cell, comprising:
forming an ion donor layer as a first electrode of the memory cell;
forming a resistive ion migration layer adjacent to the ion donor layer configured to receive free ions from the ion donor layer in response to a program bias applied to the memory cell, wherein the free ions form a conductive filament having one of multiple filament states in response to the program bias having a corresponding one of a set of signal characteristics; and
forming a diode component in electrical series with the ion donor layer and the resistive ion migration layer, wherein forming the diode component further comprises configuring the diode component for having a forward bias in a common direction as the program bias, and configuring the diode component to have a reverse bias current smaller than an erase bias current associated with deformation of the conductive filament.

16. The method of claim 15, further comprising forming a second electrode of the memory cell adjacent to the diode component.

17. The method of claim 15, further comprising forming an oxide layer that is non-permeable to the free ions between the resistive ion migration layer and the diode component.

18. The method of claim 15, wherein forming the diode component further comprises forming a p semiconductor layer adjacent to an n semiconductor layer.

19. An electronic device comprising an electronic memory unit, the electronic memory unit comprising one or more arrays of solid state multi-level memory cells configured to be one-time programmable to one of respective multiple bits of information, one of the solid state multi-level memory cells comprising:
a first electrode layer comprising free ions;
a second layer adjacent to the first electrode layer, the second layer is at least in part permeable to the free ions and facilitates formation of a conductive filament having one of a set of plural filament states that facilitates programming the one of the solid state multi-level memory cells to one of a set of multiple logical bits; and
one or more layers forming a diode component configured to mitigate deformation of the conductive filament and erasing of the one of the set of multiple logical bits.

20. The electronic device comprising of claim 19, further comprising at least two of the one or more arrays of solid state multi-level memory cells are stacked into a third dimension that is substantially perpendicular to surface areas of the one or more arrays.
